(19) United States
(12) Patent Application Publication
(10) Pub. No.: US 2021/0154722 A1
(43) Pub. Date: May 27, 2021

(54) METHOD FOR BENDING HYDROFORMED COOLING DEVICES AND BENT HYDROFORMED COOLING DEVICES

(71) Applicant: Carl Zeiss SMT GmbH, Oberkochen (DE)

(72) Inventors: Fatih Kara, Luedenscheid (DE); Joerg Zeutschel, Odenthal (DE)

(21) Appl. No.: 17/167,554

(22) Filed: Feb. 4, 2021

Related U.S. Application Data
(63) Continuation of application No. PCT/EP2019/069415, filed on Jul. 18, 2019.

(30) Foreign Application Priority Data
Aug. 7, 2018 (DE) 102018213189.9

(51) Int. Cl. B21D 26/059; B21D 9/15; G02B 5/08; G02B 27/09; G03F 7/20

(52) U.S. Cl. CPC B21D 26/059; B21D 9/15; G03F 7/70891; G02B 27/0938; G02B 5/08

(57) ABSTRACT

A method for bending a cooling device for microlithographic projection exposure apparatuses includes: providing an unbent cooling device that includes a cavity; filling the cavity with a liquid cryogenic medium at least in a region of the cooling device that is to be bent; cooling the cooling device such that the medium present in the cavity cools below its melting temperature and thereby at least partially solidifies; and bending the cooling device such that the at least partially solidified medium prevents the cavity from closing during bending.

### CROSS-REFERENCE TO RELATED APPLICATIONS

The present application is a continuation of, and claims benefit under 35 USC 120 to, international application PCT/EP2019/069415, filed Jul. 18, 2019, which claims benefit under 35 USC 119 of German Application No. 10 2018 213 189.9, filed Aug. 7, 2018. The entire disclosure of these applications are incorporated by reference herein.

### FIELD

The present disclosure relates to a method for bending hydroformed cooling devices and to bent hydroformed cooling devices. The disclosure also relates to a microlithographic projection exposure apparatus including at least one bent hydroformed cooling device.

### BACKGROUND

Microlithography is used for producing microstructured components, such as for example integrated circuits or LCDs. The microlithography process is carried out in an installation known as a projection exposure apparatus, which includes an illumination device and a projection lens. The image of a mask (=reticle) illuminated via the illumination device is in this case projected via the projection lens onto a substrate (for example a silicon wafer) coated with a light-sensitive layer (=photoresist) and arranged in the image plane of the projection lens, in order to transfer the mask structure to the light-sensitive coating of the substrate.

In projection lenses designed for the DUV range, i.e. at wavelengths of e.g. 193 nm or 248 nm, lens elements are typically used as optical elements for the imaging process.

In projection lenses designed for the EUV range, i.e. at wavelengths of e.g. approximately 13 nm or 7 nm, owing to the general lack of availability of suitable light-transmissive refractive materials, mirrors are used as optical elements for the imaging process.

In EUV and DUV projection exposure apparatuses, hydroformed, optionally plate-shaped, cooling devices are used in order to cool and/or thermally shield components in and around the beam path of microlithographic projection exposure apparatuses. So-called mini environments are thereby formed. A mini environment is understood as meaning a physical separation or encapsulation of a spatial volume, in order to produce defined environmental conditions. Thus, in an EUV projection exposure apparatus, a mini environment may include the following among its tasks/functions:
shielding what is known as the sensor frame from heat that originates from stray light, the mirror actuators, the sensors and/or the heated hydrogen in the system;
housing the beam path for protection from contamination of optical surfaces, such as mirrors.

The hydroformed, preferably plate-shaped, cooling devices can be formed as so-called pillow plates. The terms hydroformed, preferably plate-shaped, cooling device and pillow plate are used synonymously hereafter. The production of pillow plates is known art and is therefore only briefly described below on the basis of FIGS. 1, 2 and 3.

Typically (also see in this respect FIG. 1), for the production of pillow plates 100 that are profiled on one side, a thinner high-grade steel sheet 102 with a thickness of about 1-1.5 mm is placed onto a thicker high-grade steel sheet 104 with a thickness of 3-4 mm and is clamped without any gaps, for which, depending on the machine type, so-called hold-down devices are used. Depending on the application, the material strengths and also the material may vary. Subsequently, the plate-shaped sheets 102, 104 are welded to one another at the weld seams 106. In this case, the welding pattern is dependent on various factors, such as for example on the desired cooling capacity and the desired flow rates of a cooling medium. The welding patterns may be variously designed, a large number of variations being possible. For instance, in FIG. 2 a simple regular welding pattern is shown. The round weld seams 106 weld the upper sheet 102 to the lower sheet 104 (cannot be seen in FIG. 2) and provide the desired compressive stability during operation. The arrangement of the weld seams 106 dictates to what extent cavities 108, such as cooling channels, allow themselves to be hydroformed (see next paragraph). FIG. 3 shows a cooling device 100 with barriers 107. Using the barriers 107, a specific cooling medium flow can be produced. All of the cavities 108 (cannot be seen in FIG. 3) can thus be provided with the cooling medium in a defined manner. So-called dead water zones can be avoided by these barriers 107.

After the welding operation, inlet and outlet pipes are attached to the pillow plates. For this purpose, the connection points are flared and the cooling connections are welded via laser or TIG (tungsten inert gas) welding. Subsequently, the cooling channel geometry is produced by so-called hydroforming (forming using pressure via gas, water or similar media). During the hydroforming, the thinner sheet 102 is expanded in the manner of a pillow due to high pressures and due to the type of medium used. See FIG. 1 in this respect. The thicker (lower) sheet 104 is not deformed during the operation. Depending on which welding pattern is used, pressures between 30 and 100 bar are used, in order to form cavities 108 between the upper sheet 102 and the lower sheet 104. In FIG. 1, it can be seen that the arrangement of the weld seams 106 causes the pillow shape after the hydroforming. In general, the pillow plates 100 are not bent after the hydroforming, since the cavities 108 that are formed in particular as cooling channels 108 by the arrangement of the weld seams 106 may be closed again by the bending process (see FIG. 4 in this respect). The bending radius 114 plays a major role here. The smaller the bending radius 114 has to be chosen, the greater the probability that the cooling channels 108 will unwantedly close again. In FIG. 4, a cooling channel 108 that was arranged at the bending point has closed again due to the bending. The thinner sheet 102 and the thicker sheet 104 are in contact with one another again at the bending point. The dashed lines show the contours of the pillow plate 100 before the bending. The solid lines show the contours of the pillow plate 100 after the bending.

In general, a bent pillow plate with a bending radius smaller than 50 mm cannot be directly produced by hydroforming. The direct hydroforming of bent pillow plates generally involves very large bending radii from 50 mm and greater. Moreover, the direct process can involve high pressures. Pre-bent pillow plates with radii smaller than 50 mm are expensive. If it is also assumed that pillow plates with a non-cylindrical form have to be produced for use in microlithographic projection exposure apparatuses, negative molds would usually be used during the hydroforming, since the pre-bent pillow plate has a tendency to bend back into the original state due to the high pressures in the cooling channels. Moreover, in the direct hydroforming of bent pillow plates, such the pressure used can result in cracks in the laser welded seams.

Generally, the hydroformed cooling devices are bent only after they have been produced. The elements to be cooled are enclosed, at least in certain regions, by the hydroformed cooling devices. On account of the restricted installation space in microlithographic projection exposure apparatuses, the bent hydroformed cooling devices desirably have narrow bending radii smaller than 100 mm, such as down to 5 mm.

In order to keep the hydroformed cavities open during the bending of the cooling devices, the cavities may be filled with sand. The sand in the cavity helps ensures during the bending that the hydroformed regions are not drawn together again and create unwanted barriers for the cooling medium. Since the cavities have very narrow gaps as a result of the laser welding and the hydroforming, it is generally not possible for the cooling circuit to be cleaned and the grains of sand to be removed 100%. The risk of other circuits with smaller cross sections being clogged by these trapped grains of sand during operation of the pillow plates or of filters being contaminated with the grains of sand is very great. The use of an oil mixture as a cooling medium can result in a relatively high risk of contamination. In general, it is only with considerable effort that the oil mixture could be removed again from the cooling channels of the cooling device without leaving any behind.

### SUMMARY

The disclosure seeks to provide a method for bending a hydroformed cooling device and a bent hydroformed cooling device.

In an aspect, the disclosure provides a method for bending a cooling device for microlithographic projection exposure apparatuses with the following steps: providing the particularly unbent cooling device, including at least one cavity; filling the at least one cavity with a liquid cryogenic medium, at least in a region to be bent of the cooling device; cooling down the cooling device such that the medium present in the cavity cools below its melting temperature and thereby at least partially solidifies; and bending the cooling device such that the at least partially solidified medium prevents the cavity from closing during bending, in particular by its opposing forces.

In one embodiment, the at least one cavity is produced by hydroforming. The pillow-like pillow plates can be produced particularly easily by hydroforming. The number and arrangement of the cavities can be set by the number and arrangement of the weld seams.

In one embodiment, a bending radius of less than 100 mm, such as less than 50 mm, is maintained during the bending. Small bending radii of below 50 mm down to only 5 mm can be used for the use of the cooling device in microlithographic projection exposure apparatuses on account of the restricted installation space.

In one embodiment, the cryogenic medium includes a mixture of water and at least one active component and/or a solution of at least one active component in water. In this case, the active component can contain at least one surfactant, such as secondary alcohol ethoxylate, and/or at least one salt, such as potassium phosphate, sodium silicate or sodium salt. Relative to pure water, the aforementioned cryogenic medium can solidify into ice crystals of a smaller grain size when cooled down by the effect of the active component than when it is cooled down by in particular pure deionized water. Generally, the solidified cryogenic medium can be plastically deformed better than frozen pure deionized water. During the bending of the cooling device, the solidified cryogenic medium can break down into smaller fragments than frozen pure water, such as frozen pure deionized water. In an embodiment, the active component includes secondary alcohol ethoxylate, potassium phosphate, sodium silicate and at the same time sodium salt in a total amount of 15 grams per liter of mixture.

In one embodiment, the cooling down of the cooling device is performed by immersion in liquefied gas, such as in liquid nitrogen. The cooling device with the cryogenic medium can cool down relatively quickly and the cryogenic medium can thereby solidify at the same time.

In one embodiment, the bending is performed along a bending device. The bending device may be a bending machine, that is to say a forming machine tool. In the bending machine, the cooled-down cooling device, including the solidified cryogenic medium, is bent from its original form into a shaped piece. The desired bending radius can be set by the choice of the shaped piece.

In one embodiment, after the bending step, the cooling device filled with the solidified cryogenic medium is heated such that the cryogenic medium is liquefied again and the liquefied cryogenic medium can be removed from the at least one cavity in the cooling device at least almost entirely without leaving any behind. As a consequence, the cooling medium, optionally the cooling water, can flow through the cooling channels particularly well during the use of the pillow plates.

The disclosure also provides a bent, hydroformed cooling device including at least one cavity, produced, for example, by one of the aforementioned methods.

In one embodiment, the cooling device includes two or more cavities, which are in connection with one another. The pillow-like structure of the cooling device can be formed by the plurality of cavities. The pillow-like structure can allow the cooling medium to flow uniformly through the entire cooling device.

In one embodiment, the at least one cavity is formed by two sheets welded to one another, for example by a thinner sheet and a thicker sheet. The side of one of the sheets, for example the thicker sheet, that is facing a beam path in the microlithographic projection exposure apparatus can be ribbed. The propagation of stray light in the beam path can be reduced by the ribbing.

In one embodiment, the bending radius is less than approximately 100 mm, such as less than approximately 50 mm. With such small bending radii, the bent pillow plates can also be used in the greatly restricted installation space in microlithographic projection exposure apparatuses.

In one embodiment, the cooling device is arranged for the cooling and/also thermal shielding of components in and/or around a beam path in the microlithographic projection exposure apparatus. As a result, defined environments in the sense of the aforementioned mini environments can be created.

The disclosure further provides a microlithographic projection exposure apparatus with an illumination device and a projection lens, the projection exposure apparatus including at least one bent hydroformed cooling device.

### BRIEF DESCRIPTION OF THE FIGURES

Various exemplary embodiments are explained in more detail below with reference to the figures. The figures and the relative sizes of the elements shown in the figures in relation to one another should not be regarded as to scale. Rather, individual elements may be shown exaggerated in size or reduced in size to allow them to be represented better and for the sake of better understanding.

FIG. 1 shows a schematic representation of a detail of an unbent cooling device in a sectional view.

FIG. 2 shows a schematic representation of an unbent cooling device in plan view.

FIG. 3 shows a schematic representation of an unbent cooling device in plan view.

FIG. 4 shows a schematic representation of a detail of a bent cooling device in a sectional view, with a closed cavity in the region of the bending.

FIG. 5 shows a schematic representation of a detail of a bent cooling device according to the disclosure in a sectional view, with a cavity in the region of the bending, the cavity being filled with a solidified cryogenic medium.

FIG. 6 shows a schematic representation of a detail of a bent cooling device according to the disclosure in a sectional view, with a cavity in the region of the bending, the cavity having been freed of the cryogenic medium.

FIG. 7 shows a further schematic representation of a detail of a bent cooling device according to the disclosure in a sectional view, with a cavity in the region of the bending, the cavity having been freed of the cryogenic medium.

FIG. 8 shows the method steps for producing a bent cooling device according to the disclosure.

FIG. 9 shows an EUV system which includes a number of bent cooling devices according to the disclosure.

FIG. 10 shows a DUV system which can include bent cooling devices according to the disclosure.

### DISCLOSURE OF EXEMPLARY EMBODIMENTS

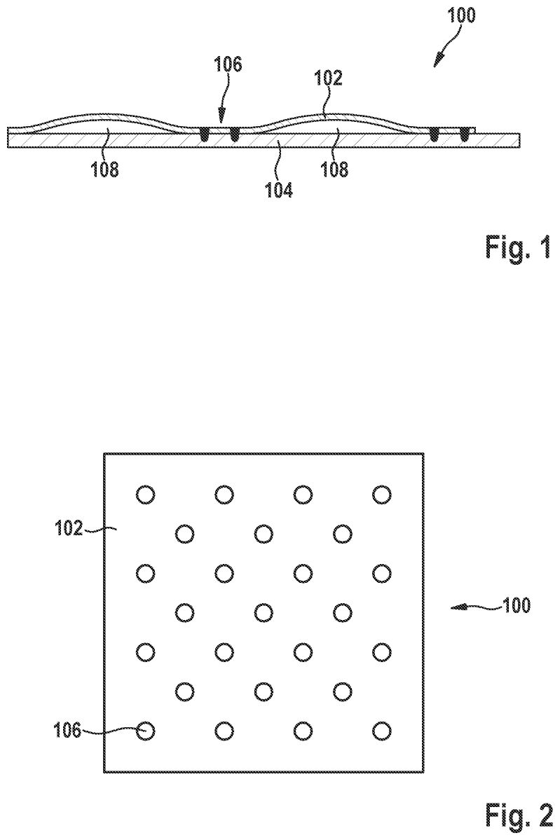

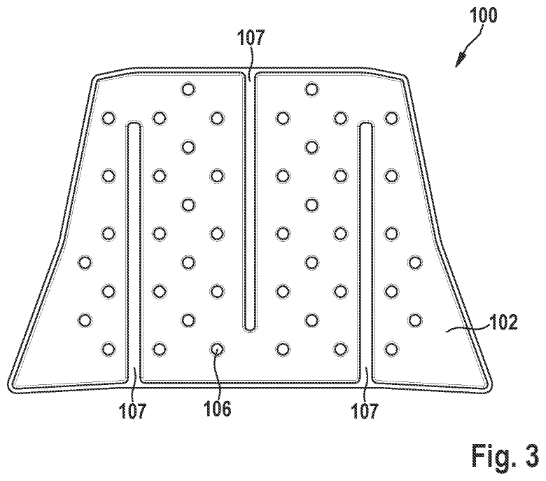

FIGS. 1, 2 and 3 show schematic representations of substantially unbent cooling devices 100 that were known. These figures have already been described in more detail in the introductory part of the description.

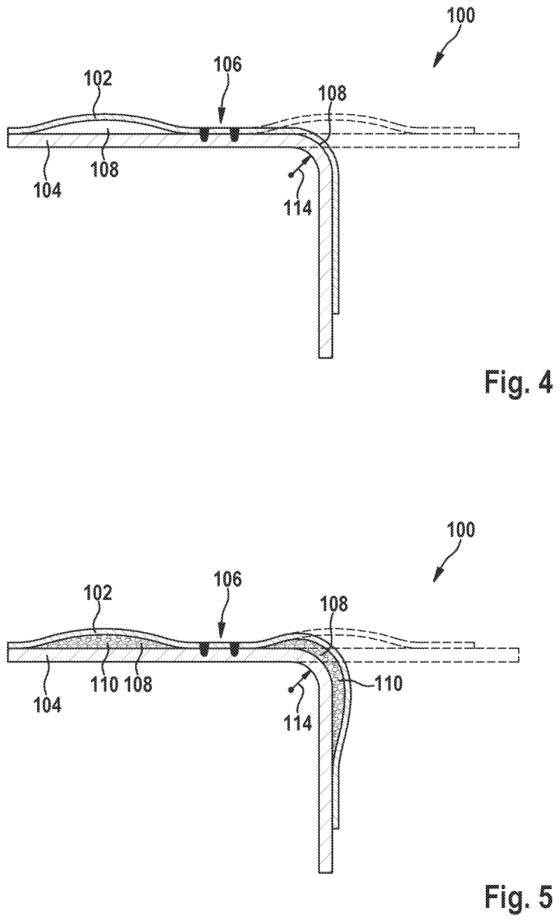

FIG. 4 shows a schematic representation of a detail of a bent cooling device 100, the cooling device 100 not having been filled with a cryogenic medium 110 before the bending. The bending radius 114 lies in this case in the range of 100 mm to 5 mm. The solid lines show the contours of the cooling device 100 after the bending. The dashed lines show the contours of the cooling device 100 before the bending. It can be seen that the cavity 108 has become at least partially closed in the bent region. The cooling medium, optionally cooling water, which is not shown in the figures, cannot flow any longer in this closed region.

FIG. 5 shows a schematic representation of a detail of a bent cooling device 100, the cooling device 100 having been filled with a cryogenic medium 110 according to the disclosure before the bending. The cryogenic medium 110 has solidified and keeps the cavity 108 open during the bending, even in the bent region. The bending radius 114 lies in this case in the range of 100 mm to 5 mm.

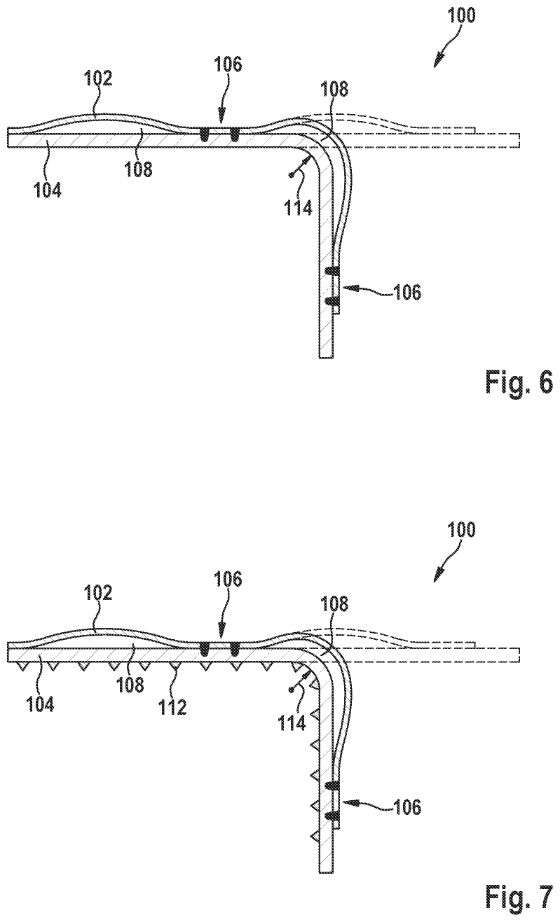

FIG. 6 shows a schematic representation of a detail of the bent cooling device 100 from FIG. 5. In FIG. 6, the cryogenic medium 110 has been removed. The cavity 108 is open, even in the bent region. The bending radius 114 lies in this case in the range of 100 mm to 5 mm.

FIG. 7 shows a schematic representation of a detail of the bent cooling device 100 from FIG. 6. In addition to FIG. 6, in FIG. 7 the side of the thicker sheet 104 that is facing a beam path in the microlithographic projection exposure apparatus is provided with a ribbing 112.

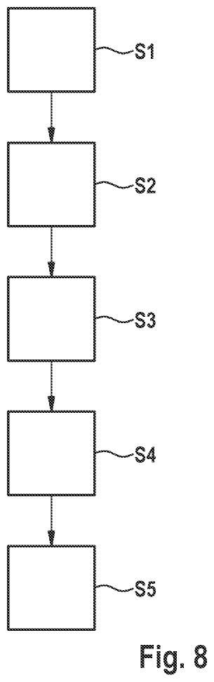

FIG. 8 shows the method for producing a cooling device 100 according to the disclosure.

The first step S1 involves providing the substantially unbent cooling device 100, including at least one cavity 108. The at least one cavity 108 was produced by hydroforming. This unbent cooling device 100 is shown in FIGS. 1, 2 and 3, which have been described in more detail in the introductory part of the description.

In the second step S2, the at least one cavity 108 is filled with a liquid cryogenic medium 110, at least in a region to be bent of the cooling device 100.

In the third step S3, the cooling device 100 is cooled down such that the cryogenic medium 110 present in the cavity 108 cools below its melting temperature and thereby at least partially solidifies. The cryogenic medium 110 is a mixture of water and at least one active component and/or a solution of at least one active component in water, the active component including, for example, at least one surfactant, such as secondary alcohol ethoxylate, and/or at least one salt, such as potassium phosphate, sodium silicate or sodium salt. The cooling down of the cooling device 100 is performed, for example, by immersion in liquefied gas, such as liquid nitrogen.

In the fourth step S4, the cooling device 100 is bent. The at least partially solidified cryogenic medium 110 prevents closing of the cavity 108 during the bending. During the bending, a bending radius 114 of less than 100 mm, such as less than 50 mm, is maintained. See FIG. 5 in this respect.

In the fifth step S5, the bent cooling device 100 filled with the at least partially solidified cryogenic medium 110 is heated such that the cryogenic medium 110 is liquefied again and the liquefied cryogenic medium 100 can be removed from the at least one cavity 108 at least almost entirely without leaving any behind. FIGS. 6 and 7 show the end result.

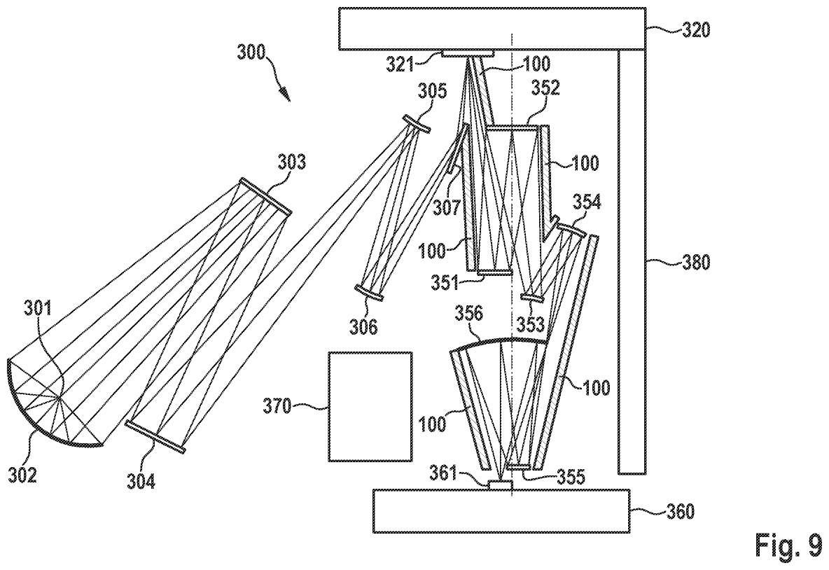

According to FIG. 9, an illumination device in a microlithographic projection exposure apparatus 300 designed for EUV includes a field facet mirror 303 and a pupil facet mirror 304. The light from a light source unit including a plasma light source 301 and a collector mirror 302 is directed onto the field facet mirror 303. A first telescope mirror 305 and a second telescope mirror 306 are arranged in the light path downstream of the pupil facet mirror 304. A grazing incidence mirror 307, which directs the radiation that is incident on it onto an object field in the object plane of a projection lens including six mirrors 351-356, is arranged downstream in the light path. Arranged on a mask stage 320 at the location of the object field is a reflective structure-bearing mask 321, an image of which is projected with the aid of the projection lens into an image plane in which a substrate 361 coated with a light-sensitive layer (photoresist) is on a wafer stage 360. The force frame 380, which substantially carries the mirrors of the projection lens, and the sensor frame 370, which substantially serves as a reference for the position of the mirrors of the projection lens, are shown roughly schematically. Some bent pillow plates 100, which substantially enclose the EUV beam path, are shown by way of example. The bending of the pillow plates 100 is not shown in FIG. 9 for reasons of overall clarity.

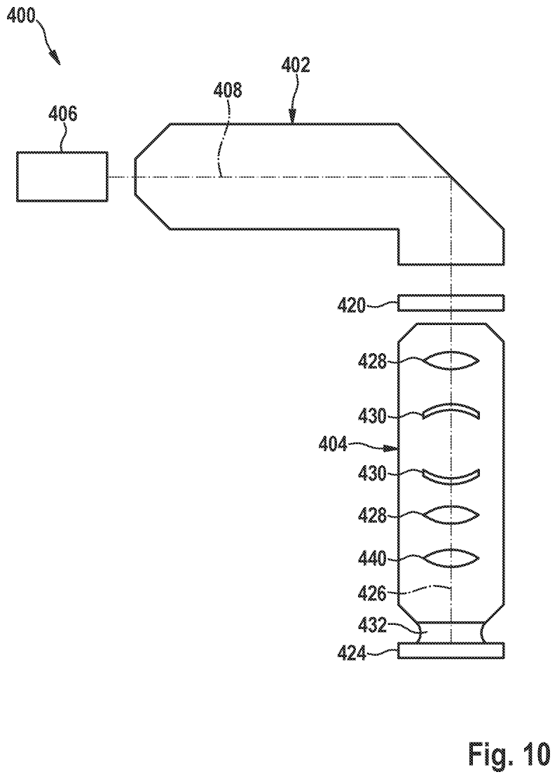

FIG. 10 shows a schematic view of a DUV projection exposure apparatus 400, which includes a beam shaping and illumination device 402 and a projection lens 404. In this case, DUV stands for “deep ultraviolet” and denotes a wavelength of the working light of between 30 and 250 nm.

The DUV projection exposure apparatus 400 includes a DUV light source 406. For example, an ArF excimer laser that emits radiation 408 in the DUV range at for example 193 nm, may be provided as the DUV light source 406.

The beam shaping and illumination device 402 shown in FIG. 10 directs the DUV radiation 408 onto a photomask 420. The photomask 420 is formed as a transmissive optical element and may be arranged outside the beam shaping and illumination device 402 and the projection lens 404. The photomask 420 has a structure of which a reduced image is projected onto a wafer 424 or the like via the projection lens 404.

The projection lens 404 has a number of lens elements 428, 440 and/or mirrors 430 for projecting an image of the photomask 420 onto the wafer 424. In this case, individual lens elements 428, 440 and/or mirrors 430 of the projection lens 404 may be arranged symmetrically in relation to the optical axis 426 of the projection lens 404. It should be noted that the number of lens elements and mirrors of the DUV projection exposure apparatus 400 is not restricted to the number shown. More or fewer lens elements and/or mirrors may also be provided. Furthermore, the mirrors are generally curved on their front side for beam shaping.

An air gap between the last lens element 440 and the wafer 424 may be replaced by a liquid medium 432 which has a refractive index of >1. The liquid medium 432 may be for example high-purity water. Such a construction is also referred to as immersion lithography and has an increased photolithographic resolution.

Even though the disclosure has been described on the basis of specific embodiments, numerous variations and alternative embodiments will be apparent to a person skilled in the art, for example through combination and/or exchange of features of individual embodiments. Accordingly, it goes without saying for a person skilled in the art that such variations and alternative embodiments are also included by the present disclosure, and the scope of the disclosure is only restricted as provided by the appended patent claims and the equivalents thereof.

### LIST OF REFERENCE SIGNS

100 Particularly plate-shaped cooling device (=pillow plate)
102 Thinner sheet
104 Thicker sheet
106 Weld seam
108 Cavity (=cooling channel)
110 Cryogenic medium
112 Ribbing
114 Bending radius
300 EUV projection exposure apparatus (=EUV system)
301 to 360 Parts of the EUV projection exposure apparatus
370 Sensor frame
380 Force frame
400 DUV projection exposure apparatus (=DUV system)
402 to 440 Parts of the DUV projection exposure apparatus

What is claimed is:

1. A method, comprising:
a) disposing a liquid cryogenic medium in a cavity of a cooling device;
b) after a), cooling the cooling device to at least partially solidify the cryogenic medium present in the cavity; and
c) after b), bending the cooling device so that the at least partially solidified cryogenic medium prevents the cavity from closing during bending.

2. The method of claim 1, further comprising, before a), using hydroforming to provide the cavity.

3. The method of claim 1, further comprising, during c), maintaining a bending radius of less than approximately 100 millimeters.

4. The method of claim 1, further comprising, during c), maintaining a bending radius of less than approximately 50 millimeters.

5. The method of claim 1, wherein the cryogenic medium comprises water and at least one member selected from the group consisting of a salt and a surfactant.

6. The method of claim 1, wherein the cryogenic medium comprises water and secondary alcohol ethoxylate.

7. The method of claim 6, wherein the cryogenic medium further comprises a salt.

8. The method of claim 6, wherein the cryogenic medium further comprises at least one member selected from the group consisting of potassium phosphate, sodium silicate and sodium salt.

9. The method of claim 1, wherein the cryogenic medium comprises water and a salt.

10. The method of claim 1, wherein the cryogenic medium comprises water and at least one member selected from the group consisting of potassium phosphate, sodium silicate and sodium salt.

11. The method of claim 1, wherein the cryogenic medium comprises at least one member selected from the group consisting of a solution comprising water and a mixture comprising water.

12. The method of claim 1, wherein b) comprises at least partially disposing the cooling device in liquefied gas.

13. The method of claim 1, wherein b) comprises at least partially disposing the cooling device in liquid nitrogen.

14. The method of claim 1, further comprising, after c):
heating the cooling device to liquefy the cryogenic medium; and
removing the cryogenic medium from the cavity.

15. The method of claim 1, wherein a) comprises filling the cavity of the cooling device with the liquid cryogenic medium,

16. The method of claim 1, further comprising, after c), using the cooling device in a microlithographic projection exposure apparatus.

17. An apparatus, comprising:
an illumination device comprising a plurality of optical elements;
a projection lens comprising a second plurality of optical elements; and
a cooling device comprising a first sheet and a second sheet different from the first sheet,
wherein:
the illumination device is configured to illuminate an object in an object plane of the projection lens;
the projection lens is configured to image the illuminated object onto a light-sensitive material in an image plane of the projection lens;
the cooling device comprises a cavity between the first and second sheets;
the cavity has a bending radius of less than approximately 100 millimeters; and
the cooling device is configured to cool at least one optical element selected from the group consisting of the first plurality of optical elements and the second plurality of optical elements.

18. The apparatus of claim 17, wherein the at least one optical element comprises a mirror.

19. The apparatus of claim 17, wherein:
during use of the apparatus, light follows a path from a light source to the object via the illumination device and from the object to the light-sensitive material via the projection lens; and
the first sheet comprises ribbing facing the path of the light.

20. The apparatus of claim 19, wherein the first sheet is thicker than the second sheet.
